(19) United States
(12) Patent Application Publication
(10) Pub. No.: US 2017/0269400 A1
(43) Pub. Date: Sep. 21, 2017

(54) Polymeric Dispersed Liquid Crystal Light Shutter Device and System and Method for Forming the Same

(71) Applicant: Polytronix, Inc., Richardson, TX (US)

(72) Inventors: Robert Northrup, Richardson, TX (US); Menting Tim Tsai, Plano, TX (US)

(21) Appl. No.: 15/073,153

(22) Filed: Mar. 17, 2016

(51) Int. Cl. G02F 1/1334; G03F 1/50; G03F 7/20; G02F 1/137

(52) U.S. Cl. CPC G02F 1/1334; G02F 1/137; G03F 1/50; G03F 7/2002

(57) ABSTRACT

A polymeric dispersed liquid crystal light shutter device employing an electronically tunable lens and system and method for forming the same are disclosed. In one embodiment of the system, a patterned UV-photomask with an image is superposed on a pre-cure or un-cured polymer dispersed liquid crystal (PDLC) light shutter device having liquid crystals dispersed in a polymer binder system between two substrates. UV-light is applied during curing. The liquid crystal microdroplet sizes vary according to the image on the patterned mask such that domains of larger liquid crystal microdroplet sizes correspond to the image and domains of smaller liquid crystal microdroplet sizes correspond to negative space relative to the image. Upon tuning an electric field, the PDLC light shutter device changes states from presenting a surface having an image formed by partially-scattering regions contrasted against clear non-scattering regions, to a surface characterized by mostly or entirely clear, non-scattering light transmittance.

### TECHNICAL FIELD OF THE INVENTION

This invention relates, in general, to liquid crystal display technology and, in particular, to polymer dispersed liquid crystal (PDLC) light shutter devices that include formulations of liquid crystal mixtures having nematic liquid crystals and polymer systems to provide visual effects.

### BACKGROUND OF THE INVENTION

A liquid crystal display can show an image using electro-optical characteristics of a liquid crystal, which is injected into a space defined by two substrates. The electro-optical characteristics of the liquid crystals appear when electric power is applied thereto. Such a liquid crystal display is classified as one of a variety of types including twisted nematic (TN), super twisted nematic (STN), dynamic scattering mode (DSM), and the aforemented PDLC, for example. Liquid crystal shutters are useful in various applications concerning the transmittance of light through an aperture in which it should be possible to switch the shutter between a low transmission state and a high transmission state, in response to a change in the electric influence.

PDLCs consist of micron-size droplets of low-molecular weight nematic liquid crystals dispersed in a polymer binder system. A PDLC material is sandwiched between substrates having a transparent conducting electrode such as indium tin oxide, to form a shutter. Upon application of a voltage across the electrodes of the shutter, a switching occurs from an opaque, high scattering state to a clear, transparent state. PDLC materials are formed by phase separation of low-molecular weight liquid crystals from a homogeneous solution with pre-polymer or polymer. The size, shape and density of the liquid crystal droplets depend on the techniques implemented. With existing shutters, solutions have been proposed over the years for selectively providing a tunable lens. Many of the existing devices, however, require the liquid crystal material be aligned on convex curved substrates or concave curved substrates, where it is extremely difficult to align the liquid crystal molecules on the curved substrates. Additionally, most of these devices require linearly polarized light sources in order to operate. Accordingly improvements are needed.

### SUMMARY OF THE INVENTION

It would be advantageous to provide a tunable lens in a PDLC system. It would also be desirable to enable a chemical-based solution that would mitigate the need for convex or concave substrates and the request for linearly polarized light. To better address one or more of these concerns, a polymeric dispersed liquid crystal light shutter device employing an electronically tunable image is disclosed. In one embodiment of the system, a patterned UV-photomask with an image is superposed on a pre-cure or un-cured PDLC light shutter device having liquid crystals dispersed in a polymer binder system between two substrates. UV-light is applied during curing. The liquid crystal microdroplet sizes vary according to the image on the patterned mask such that domains of larger liquid crystal microdroplet sizes correspond to the image and domains of smaller liquid crystal microdroplet sizes correspond to negative space relative to the image.

Upon tuning an electric field, the PDLC light shutter device changes states from presenting a surface having an image formed by partially-scattering regions contrasted against clear non-scattering regions, to a surface characterized by mostly or entirely clear, non-scattering light transmittance. A corresponding PDLC light shutter device and method for forming the same are additionally disclosed. These and other aspects of the invention will be apparent from and elucidated with reference to the embodiments described hereinafter.

### BRIEF DESCRIPTION OF THE DRAWINGS

For a more complete understanding of the features and advantages of the present invention, reference is now made to the detailed description of the invention along with the accompanying figures in which corresponding numerals in the different figures refer to corresponding parts and in which:

FIG. 1 is a diagrammatic view of one embodiment of a liquid crystal shutter being utilized to provide each of an opaque, high scattering state, a translucent, image state, and a clear, transparent state;

FIG. 2 is a diagrammatic view of another embodiment of a liquid crystal shutter being utilized to provide each of an opaque, high scattering state, a translucent, image state, and a clear, transparent state;

FIG. 3 is a diagrammatic view of one embodiment of the liquid crystal shutter depicted in FIG. 1 in a high scattering opaque state;

FIG. 4 is a diagrammatic view of one embodiment of the liquid crystal shutter depicted in FIG. 1 in a translucent, image state;

FIG. 5 is a diagrammatic view of one embodiment of the liquid crystal shutter depicted in FIG. 1 in a low scattering transparent state; and

FIG. 6 is a diagrammatic view of one embodiment of a methodology and process for forming polymeric dispersed liquid crystal light shutter device employing an electronically tunable lens.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention, and do not delimit the scope of the present invention.

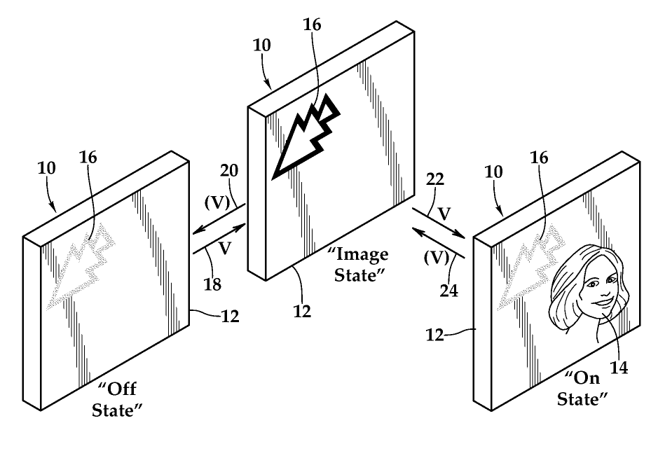

Referring initially to FIG. 1, therein is depicted a PDLC light shutter device or, more succinctly, a liquid crystal shutter that is schematically illustrated and generally designated 10. Liquid crystals are substances that exhibit a phase of matter that has properties between those of a conventional liquid, and those of a solid crystal. For instance, a liquid crystal may flow like a liquid, but have the molecules in the liquid arranged and/or oriented in a crystal-like way. One type of liquid crystal, in the aforementioned polymer dispersed liquid crystal or PDLC, comprises micro-size droplets of low-molecular weight nematic liquid crystals dispersed in a polymer binder system. The liquid crystal shutter 10 includes a PDLC material interposed between substrates having transparent conducting electrodes. In FIG. 1, the liquid crystal shutter 10 is being utilized as a window 12, behind which, an individual 14 is standing. Moreover, as shown, the liquid crystal shutter 10, in response to electronic tuning, includes an image 16, which may be a logo, a graphic mark, an emblem, a symbol, or words, for example.

Upon application of a voltage across the electrodes of the liquid crystal shutter 10, as shown by arrow 18, the liquid crystal shutter 10, switches from an opaque, high scattering state, labeled as an “OFF State” to a translucent, image state, labeled “IMAGE State,” wherein the image 16 is visible. Upon removal of the voltage (V), as shown by arrow 20, the liquid crystal shutter 10 switches from the translucent, image state to the opaque, high scattering state. Continuing with the discussion of the “IMAGE State,” upon the application of a further voltage across the electrodes of the liquid crystal shutter 10, as shown by arrow 22, the liquid crystal shutter 10 switches from the translucent, image state to a clear, transparent state, labeled as the “ON State,” wherein the individual 14 can be seen standing behind the window 12. As shown by arrow 24, by the reduction in voltage, the “ON State” returns to the “IMAGE State.” It should be appreciated that although the liquid crystal shutter is presented as a window, the teachings presented herein extend to any type of aperture including apertures for looking through, apertures having a need for clear and opaque states, switchable glass, privacy glass, smart windows, smart glasses. Further the light crystal shutter may be glass, plexiglass, polycarbonate or other material as will be discussed hereinbelow.

FIG. 2 is a diagrammatic view of another embodiment of a liquid crystal shutter 10 being utilized to provide each of an opaque, high scattering state, a translucent, image state, and a clear, transparent state. As shown, by electronically tuning the PDLC shutter device with the application and reduction of voltage as shown by arrows 18, 20, 22, and 24, the PDLC shutter device is selectively tunable among the “OFF State,” “IMAGE State,” and “ON State.” Depending on the curing parameters, in one embodiment, the image 16 may be partially visible in either the “OFF State,” the “ON State,” or both.

As previously mentioned, liquid crystal lens have been proposed over the years for selectively controlling the index of refraction of light passing through the lens such that a gradient-index liquid crystal lens with a tunable focal length is provided. In one embodiment of the liquid crystal shutter 10, a flat profile is provided such that an alignment on convex curved substrates or concave curved substrates is not necessary. Further, a linearly polarized light source is not necessary in order to operate and, for example, view the individual 14. In one implementation, the polymer binder system may include light curable adhesives selected from the group consisting of acrylates, methacrylates, thiolene-based polyurethanes, and mercapto-esters with a photoinitiator.

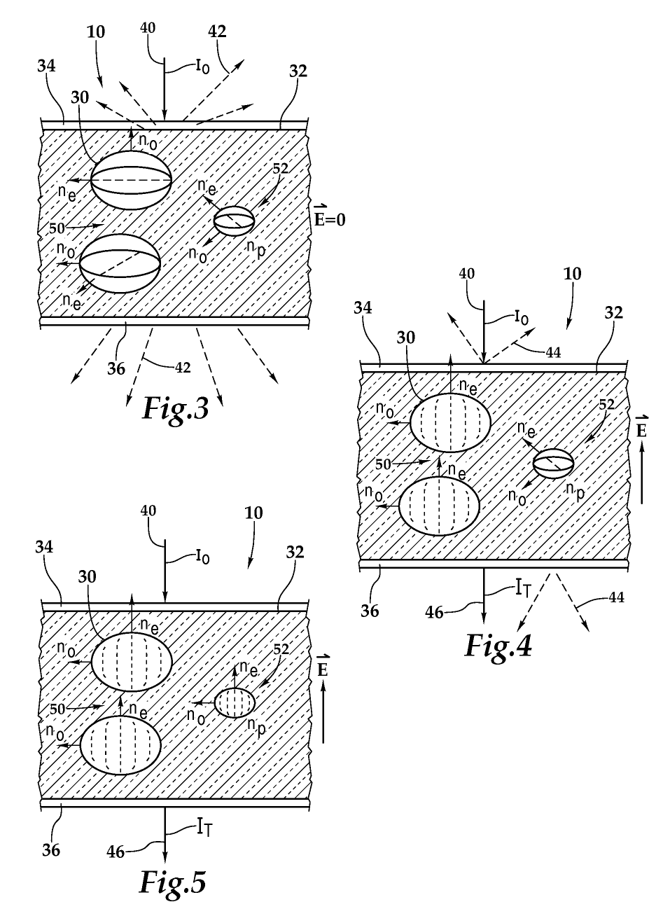

FIG. 3 depicts one embodiment of the liquid crystal shutter 10 wherein encapsulated liquid crystal microdroplets 30 are distributed uniformly in a polymer binder system 32, which may have the form of a plastic matrix, to create the PDLC material that is then sandwiched between two transparent substrates 34, 36. In one implementation, the substrates 34, 36 are positioned parallel or substantially parallel to each other and include a transparent body having a transparent conducing layer therewith. The transparent body may be selected from materials consisting of glasses and plastics, for example. Moreover, the transparent body may include a refractive index from about 1.51 to about 1.52. The polymer binder system 32 may also have a refractive index from about 1.51 to about 1.52. It should be appreciated that the refractive indexes of the transparent substitutes 34, 36 and the polymer binder system 32 are matched as close as possible to improve transparency. The transparent conducting layer may comprise an indium-tin-oxide conducting layer or other suitable conducting layer, for example.

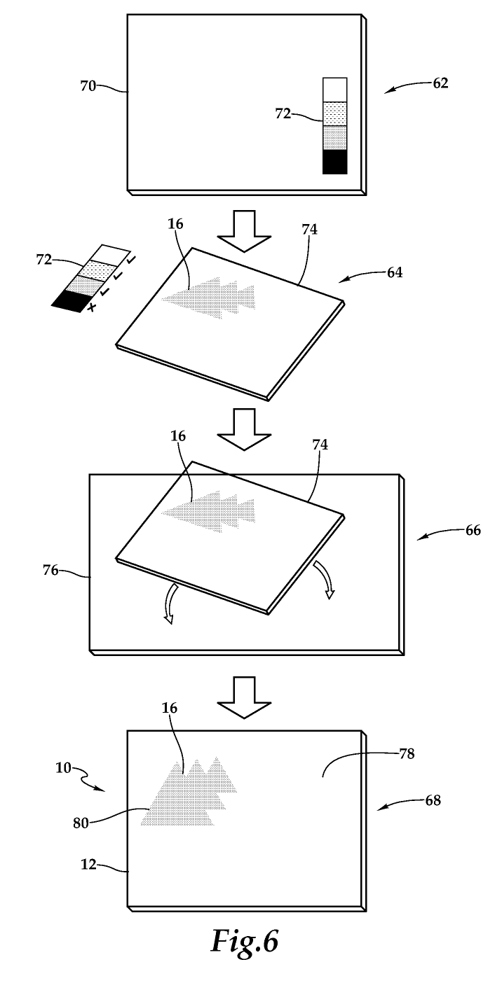

As illustrated, the liquid crystal shutter 10 includes inhomogeneous droplet size distributions of the liquid crystal microdroplets 30 in the polymer binder system 32, which as will be discussed in FIG. 6, are formed by exposing UV light to the LC/monomer mixture through a patterned mask, for example. The inhomogeneous droplet size distribution includes a large domain 50 and a small domain 52. In the brighter region corresponding to absence of the patterned mask, the polymerization rate is faster resulting in smaller liquid crystal microdroplets 30 at the small domain 52. In the weaker UV exposure regions corresponding to the presence of the patterned mask, the liquid crystal microdroplets 30 are larger at the large domain 50. It should be appreciated that the gradient of liquid crystal microdroplet sizes can vary from approximately a few nanometers to micrometers, depending on formation characteristics.

FIG. 3, which is an “OFF State” shows a light scattering state of the liquid crystal microdroplets 30 in the polymer binder system 32, in the absence of an applied electric field. Within each of the liquid crystal microdroplets 30, liquid crystals have tangential wall alignment; however, there is a two dimension random orientation of molecules in comparing various liquid crystal microdroplets 30. In terms of optical properties, this corresponds to a highly light scattering state.

That is, in the absence of an applied electric field (\vec{E}=0), the optic axes of the liquid crystal microdroplets 30 have no preferred direction in which to point in the plane, so that incident light encounters a mismatch between the refraction index (nₚ) of the matrix and the effective refraction index (˜n_{eff}) of the liquid crystal microdroplets. The result of the mismatch is that the light is scattered and the liquid crystal shutter 10 appears opaque. On the other hand, if an electrical field (\vec{E}) is applied as shown in FIG. 3 and FIG. 4, the orientations of molecules among various microdroplets is completely aligned. The applied electric field (\vec{E}) aligns the directors within the droplets to a partial or completely transparent state such that n_{eff}→nₒ=nₚ when → is \vec{E} at high field.

With reference to the light scattering state of FIG. 3, the optic axis of the droplets is indicated by nₑ. If the ordinary refractive index of the liquid crystal, n₀, matches that of the polymer binder system 32, nₚ, then light scatters according to the value and orientation distribution of nₑ. In a low field, if n_{eff} is close to nₑ and nematic directors are randomly oriented (OFF state), light is strongly scattered. If nₑ is reoriented to be parallel to the direction of normally incident light, as in the case under an applied electric field, then, in principle, no light is scattered (n₀˜nₚ). It should be appreciated that the liquid crystal microdroplets may be fabricated as spherical or elliptical shapes and that the shape of the liquid crystal microdroplets may change shape and size due to other factors when the liquid crystal shutter 10 is assembled, as the liquid crystal microdroplets are compressed in combination before curing has begun.

By way of illustration, the “effective” refractive index, which may the “average,” approaches the “extraordinary” at a maximum. By way of example, if “ordinary” or n₀ is 1.52, the polymer or nₚ is 1.52, and the “extraordinary” or nₑ is 1.56, the “effective” or n_{eff} is 1.52 i.e. equals the ordinary in a strong electric field, but can move to 1.56 as incident light encounters the nₑ in the OFF or no-electric field scattering state.

As mentioned, in FIG. 4, in response to an application of an electric field (\vec{E}=↑) across the transparent substrates 34, 36, the liquid crystal shutter 10 provides for the partial transmission of light to cause an “IMAGE State”. The electric field causes the optic axes of the liquid crystal microdroplets 30 in the large domain 50 to align parallel to the field and normal to the surfaces of the transparent substrates 34, 36. The optic axes of the liquid crystal microdroplets 30 in the small domain 52, on the other hand, have no preferred direction in which to point in the plane, so that incident light encounters a mismatch between the refraction index nₚ of the matrix and the average refraction index (˜nₑ) of the liquid crystal microdroplets. The result of the mismatch is that the light is scattered and, with respect to the small domain 52, the liquid crystal shutter 10 appears opaque.

In this transmission state, which may be an “ON STATE,” incident light 40 detects no mismatch between average refractive index of the liquid crystal droplets (˜n₀) with respect to the large domain and the polymer binder system 32 (nₚ) and light is transmitted so that the image 16 within the liquid crystal shutter 10 appears clear.

As mentioned, in FIG. 5, in response to an application of an electric field (\vec{E}=↑) across the transparent substrates 34, 36, the liquid crystal shutter 10 provides transmission of light. The electric field causes the optic axes of the liquid crystal microdroplets 30 in both the large domain 50 and the small domain 52 to align parallel to the field and normal to the surfaces of the transparent substrates 34, 36. In this transmission state, incident light 40 detects no mismatch between average refractive index of the liquid crystal droplet (˜n₀) and the polymer binder system 32 (nₚ) and light 46 is transmitted so that the liquid crystal shutter 10 appears clear. As mentioned, by the application and removal of the driving voltage the liquid crystal shutter 10 may be alternated between the light scattering state of FIG. 3, the partial scattering of FIG. 4 and the light transmission state of FIG. 5.

With reference to FIGS. 3 through 5, in the voltage OFF state of FIG. 3, the liquid crystal shutter 10 is non-transparent and light scattering is observed as oriented directions of the liquid crystal microdroplets 30 are random. This is because the droplet sizes are much smaller than the wavelength. As the voltage is applied to the liquid crystal shutter 10 as shown in FIG. 4 and FIG. 5, the liquid crystal microdroplets are reoriented along the electric field direction. The turn ON voltage of such liquid crystal microdroplets 30 depends on the droplet sizes: the smaller the droplet, the higher the threshold voltage. As a result, the gradient refractive index profile is generated that initially permits incident light 40 to be partially scattered as scattered light 44 by the small domains 52 and transmitted by the large domains 50, giving rise to transmitted light 46 and the appearance of the image 16. In one embodiment, as the voltage increases, all of the domains, including the large domain 50 and the small domain 52, are aligned such that incident light 40 is transmitted as transmitted light 46.

With respect to the driving voltage characteristics of FIGS. 4 and 5, a lower voltage for image distinction/visualization, for example, from about 14 V to about 50 V AC range, may be utilized in FIG. 4. For privacy, ON at higher ranges in FIG. 5, for example, may be from about 65 V to about 110 V AC. With mild photomasking, e.g. low-density ink photomask, the image can be hidden in both OFF and full ON voltage range as shown in FIG. 1. With stronger photomasking, the image will always be somewhat noticeable, in OFF and full ON voltages as shown in FIG. 2. Voltage correlates to liquid crystal domain size. The experimental data suggests areas of blocked light (low UV) require higher driving voltage to turn clear, however other adhesives have shown the opposite effect—areas of higher UV intensity cure can require higher driving voltage to turn clear. Generally, depending on adhesive and liquid crystal choice, across the varied cure intensity areas created by photomasking, a PDLC film will turn clear at distinct voltage ranges. By way of example, 24 V AC to clear one region, 110 V AC to clear a second, except in the case of gradients, which drop or rise in light transmission along the function of the gradient (linear, logarithmic). By way of further example, a transparent substrate printed with ink may be employed as a photomask. This may have the form of a poly (ethylene terephthalate) or PET.

FIG. 6 depicts one embodiment of a methodology and process for forming a PDLC light shutter device employing an electronically tunable lens. In one embodiment, ink, pigment or masking with absorption in light curable adhesive ranges, generally from about 300 nm to about 700 nm bandwidth. Ink and pigments with absorption peak or shoulder in of about 340 nm to about 410 nm UVA range is also applicable. The method for application includes adhesion or close contact of photomasking material to flat sheet of PDLC laminate during curing and the creation of the photomask can be done by inkjet printer with, for example, black ink in a half tone patterning, or UV-curing ink print head with, for example, yellow ink in a gradient, photo negative or positive.

More specifically, at step 62, a test run is conducted wherein a PDLC regular cure substrate 70 and an exposure gradient 72 are subjected to a UV light treatment. In one embodiment, the exposure gradient 72 may be a Stouffer Scale, for example, that measures exposure. At step 64, a patterned photomask 74, which may be a patterned UV-photomask, is provided having the image 16 thereon. The exposure gradient 72 allows for the selection of appropriate exposure or exposures. At step 66, a pre-cure or un-cured light shutter device 76 having a flat profile is provided, which may include two substrates disposed substantially parallel and a polymer binder system interposed between the substrates with a plurality of liquid crystals dispersed in the polymer binder system.

Continuing with the description of step 66, the patterned photomask 74 is superposed on the substrate of the pre-cure or un-cured light shutter device 76. Then, light is applied in the range of about 300 nm to about 700 nm to cure the liquid crystal microdroplet sizes. It should be appreciated that in some applications a narrower band of UV-light is applied from a light source or a UV-light source. The liquid crystals include inhomogeneous liquid crystal microdroplet sizes corresponding to the patterned photomask 74 having the image thereon. More particularly, the liquid crystal microdroplet sizes vary according to the image on the patterned mask such that domains of larger liquid crystal microdroplet sizes correspond to the image and another domain of smaller liquid crystal microdroplet sizes correspond to negative space relative to the image.

At step 68, the patterned photomask 74 is removed from the substrate and the light shutter device 76 is cured, thereby providing the liquid crystal light shutter device 12 having a flat profile. The image 16 is a sufficiently cured region 80 while the negative space relative to the image is a fully cured region 78. Once formed, the light shutter device 12 provides, in absence of an application of an electric field across the substrates, optic axes of the liquid crystal microdroplets of the larger and smaller domains with no preferred direction and light is scattered, whereby the liquid crystal shutter 10 appears opaque.

The light shutter device 12 provides, in response to an application of a first electric field across the first and second substrates, the optic axes of the liquid crystal microdroplets of the various domains have an aligned direction and light is transmitted therethrough, the optic axes of the liquid crystal microdroplets of the second domains have no preferred direction and light is scattered, whereby the liquid crystal shutter 10 appears opaque with an image thereon. The light shutter device also provides, in response to an application of a second electric field across the first and second substrates, the optic axes of the liquid crystal microdroplets of the first and second domains have an aligned direction and light is transmitted therethrough, whereby the liquid crystal shutter 10 appears transparent.

The order of execution or performance of the methods and process flows illustrated and described herein is not essential, unless otherwise specified. That is, elements of the methods and process flows may be performed in any order, unless otherwise specified, and that the methods may include more or less elements than those disclosed herein. For example, it is contemplated that executing or performing a particular element before, contemporaneously with, or after another element are all possible sequences of execution.

While this invention has been described with reference to illustrative embodiments, this description is not intended to be construed in a limiting sense. Various modifications and combinations of the illustrative embodiments as well as other embodiments of the invention, will be apparent to persons skilled in the art upon reference to the description. It is, therefore, intended that the appended claims encompass any such modifications or embodiments.

What is claimed is:

1. A polymer dispersed liquid crystal light shutter device comprising:
first and second substrates disposed substantially parallel to provide a flat profile;
a polymer binder system interposed between the first and second substrates;
a plurality of liquid crystals dispersed in the polymer binder system, the plurality of liquid crystals including inhomogeneous liquid crystal microdroplet sizes corresponding to a patterned mask having an image thereon, the liquid crystal microdroplet sizes varying according to the image on the patterned mask such that first domains of larger liquid crystal microdroplet sizes correspond to the image and second domains of smaller liquid crystal microdroplet sizes correspond to negative space relative to the image;
in absence of an application of an electric field across the first and second substrates, optic axes of the liquid crystal microdroplets of the first and second domains have no preferred direction and light is scattered, whereby the liquid crystal shutter appears opaque;
in response to an application of a first electric field across the first and second substrates, the optic axes of the liquid crystal microdroplets of the first domains have an aligned direction and light is transmitted therethrough, the optic axes of the liquid crystal microdroplets of the second domains have no preferred direction and light is scattered, whereby the liquid crystal shutter appears opaque with an image thereon; and
in response to an application of a second electric field across the first and second substrates, the optic axes of the liquid crystal microdroplets of the first and second domains have an aligned direction and light is transmitted therethrough, whereby the liquid crystal shutter appears transparent.

2. The polymer dispersed liquid crystal light shutter device as recited in claim 1, wherein the first and second substrates further comprises an indium-tin-oxide conducting layer.

3. The polymer dispersed liquid crystal light shutter device as recited in claim 1, wherein the polymer binder system further comprises a plurality of light curable adhesives selected from the group consisting of acrylates, methacrylates, thiolene-based polyurethanes, and mercapto-esters with a photoinitiator.

4. The polymer dispersed liquid crystal light shutter device as recited in claim 1, wherein the first electric field is driven by a voltage of about 14 V to about 50 V.

5. The polymer dispersed liquid crystal light shutter device as recited in claim 1, wherein the second electric field is driven by a voltage of about 65 V to about 110 V.

6. A system for forming a polymer dispersed liquid crystal light shutter device, the system comprising:
a patterned photomask having an image thereon;
first and second substrates disposed substantially parallel to provide a flat profile;
a polymer binder system interposed between the first and second substrates;
a plurality of liquid crystals dispersed in the polymer binder system, the plurality of liquid crystals including inhomogeneous liquid crystal microdroplet sizes corresponding to the patterned photomask having the image thereon, the liquid crystal microdroplet sizes varying according to the image on the patterned mask such that first domains of larger liquid crystal microdroplet sizes correspond to the image and second domains of smaller liquid crystal microdroplet sizes correspond to negative space relative to the image,
whereby selectively temporarily close contact of the patterned photomask with the first substrate and application of light in the range of about 300 nm to 700 nm cures the liquid crystal microdroplet sizes, the patterned photomask being interposed between a light source and the first substrate;
in absence of an application of an electric field across the first and second substrates, optic axes of the liquid crystal microdroplets of the first and second domains have no preferred direction and light is scattered, whereby the liquid crystal shutter appears opaque;
in response to an application of a first electric field across the first and second substrates, the optic axes of the liquid crystal microdroplets of the first domains have an aligned direction and light is transmitted therethrough, the optic axes of the liquid crystal microdroplets of the second domains have no preferred direction and light is scattered, whereby the liquid crystal shutter appears opaque with an image thereon; and
in response to an application of a second electric field across the first and second substrates, the optic axes of the liquid crystal microdroplets of the first and second domains have an aligned direction and light is transmitted therethrough, whereby the liquid crystal shutter appears transparent.

7. The system as recited in claim 6, wherein the first and second substrates further comprises an indium-tin-oxide conducting layer.

8. The system as recited in claim 6, wherein the polymer binder system further comprises a plurality of light curable adhesives selected from the group consisting of acrylates, methacrylates, thiolene-based polyurethanes, and mercapto-esters with a photoinitiator.

9. The system as recited in claim 6, wherein the first electric field is driven by a voltage of about 14 V to about 50 V.

10. The system as recited in claim 6, wherein the second electric field is driven by a voltage of about 65 V to about 110 V.

11. The system as recited in claim 6, wherein the photomask further comprises a transparent substrate printed with ink from an inkjet printer.

12. The system as recited in claim 6, wherein the application of light further comprises the range of about 340 nm to about 410 nm.

13. A method for forming a polymer dispersed liquid crystal light shutter device, the method comprising:
providing a patterned photomask having an image thereon;
providing a pre-cure polymer dispersed liquid crystal light shutter device having a flat profile comprising:
first and second substrates disposed substantially parallel,
a polymer binder system interposed between the first and second substrates, and
a plurality of liquid crystals dispersed in the polymer binder system;
superposing the patterned photomask on the first substrate;
applying light in the range of about 300 nm to about 700 nm to cure the liquid crystal microdroplet sizes, whereby the plurality of liquid crystals includes inhomogeneous liquid crystal microdroplet sizes corresponding to the patterned photomask having the image thereon, the liquid crystal microdroplet sizes varying according to the image on the patterned mask such that first domains of larger liquid crystal microdroplet sizes correspond to the image and second domains of smaller liquid crystal microdroplet sizes correspond to negative space relative to the image;
removing the photomask from the first substrate, thereby providing a polymer dispersed liquid crystal light shutter device having a flat profile;
providing, in absence of an application of an electric field across the first and second substrates, optic axes of the liquid crystal microdroplets of the first and second domains have no preferred direction and light is scattered, whereby the liquid crystal shutter appears opaque;
providing, in response to an application of a first electric field across the first and second substrates, the optic axes of the liquid crystal microdroplets of the first domains have an aligned direction and light is transmitted therethrough, the optic axes of the liquid crystal microdroplets of the second domains have no preferred direction and light is scattered, whereby the liquid crystal shutter appears opaque with an image thereon; and
providing, in response to an application of a second electric field across the first and second substrates, the optic axes of the liquid crystal microdroplets of the first and second domains have an aligned direction and light is transmitted therethrough, whereby the liquid crystal shutter appears transparent.

14. The method as recited in claim 13, wherein providing a pre-cure polymer dispersed liquid crystal light shutter device further comprises providing the first and second substrates including an indium-tin-oxide conducting layer.

15. The method as recited in claim 13, wherein providing a pre-cure polymer dispersed liquid crystal light shutter device further comprises providing the polymer binder system further including a plurality of light curable adhesives selected from the group consisting of acrylates, methacrylates, thiolene-based polyurethanes, and mercapto-esters with a photoinitiator.

16. The method as recited in claim 13, wherein providing the first electric field further comprises driving a voltage of about 14 V to about 50 V.

17. The method as recited in claim 13, wherein providing the second electric field further comprises driving a voltage of about 65 V to about 110 V.

18. The method as recited in claim 13, wherein providing a patterned photomask further comprises providing a transparent substrate printed with ink from an inkjet printer.

19. The method as recited in claim 13, wherein applying light further comprises providing the application of light in the range of about 340 nm to about 410 nm.

20. A method for forming a polymer dispersed liquid crystal light shutter device, the method comprising:
providing a patterned UV-photomask having an image thereon, the patterned UV-photomask including a transparent substrate printed with ink from an inkjet printer;
providing a pre-cure polymer dispersed liquid crystal light shutter device having a flat profile comprising:
first and second substrates disposed substantially parallel, the first and second substrates including an indium-tin-oxide conducting layer,
a polymer binder system interposed between the first and second substrates, the polymer binder system including a plurality of light curable adhesives selected from the group consisting of acrylates, methacrylates, thiolene-based polyurethanes, and mercapto-esters with a photoinitiator, and
a plurality of liquid crystals dispersed in the polymer binder system;
superposing the patterned UV-photomask on the first substrate;
applying UV-light in the range of about 340 nm to about 410 nm to cure the liquid crystal microdroplet sizes, whereby the plurality of liquid crystals includes inhomogeneous liquid crystal microdroplet sizes corresponding to the patterned UV-photomask having the image thereon, the liquid crystal microdroplet sizes varying according to the image on the patterned mask such that first domains of larger liquid crystal microdroplet sizes correspond to the image and second domains of smaller liquid crystal microdroplet sizes correspond to negative space relative to the image;
removing the UV-photomask from the first substrate, thereby providing a polymer dispersed liquid crystal light shutter device having a flat profile;
providing, in absence of an application of an electric field across the first and second substrates, optic axes of the liquid crystal microdroplets of the first and second domains have no preferred direction and light is scattered, whereby the liquid crystal shutter appears opaque;
driving a voltage of about 14 V to about 50 V to apply a first electric field across the first and second substrates, the optic axes of the liquid crystal microdroplets of the first domains have an aligned direction and light is transmitted therethrough, the optic axes of the liquid crystal microdroplets of the second domains have no preferred direction and light is scattered, whereby the liquid crystal shutter appears opaque with an image thereon; and
driving a voltage of about 65 V to about 110 V to apply a second electric field across the first and second substrates, the optic axes of the liquid crystal microdroplets of the first and second domains have an aligned direction and light is transmitted therethrough, whereby the liquid crystal shutter appears transparent.
